(19) United States
(12) Patent Application Publication
(10) Pub. No.: US 2011/0102102 A1
(43) Pub. Date: May 5, 2011

(54) DUPLEXER

(75) Inventors: Kouhei FUJIO, Nagaokakyo-shi (JP); Takashi MIYAKE, Nagaokakyo-shi (JP); Keiichi UMEDA, Nagaokakyo-shi (JP); Kenichi UESAKA, Nagaokakyo-shi (JP)

(73) Assignee: MURATA MANUFACTURING CO., LTD., Nagaokakyo-shi (JP)

(21) Appl. No.: 12/985,366

(22) Filed: Jan. 6, 2011

Related U.S. Application Data
(63) Continuation of application No. PCT/JP2009/053284, filed on Feb. 24, 2009.

(30) Foreign Application Priority Data
Jul. 17, 2008 (JP) 2008-185518

(51) Int. Cl. H03H 9/70; H03H 9/72

(52) U.S. Cl. 333/133; 333/187; 333/195

(57) ABSTRACT

A duplexer that achieves a reduction in the size and an increase in the performance includes a transmission filter including piezoelectric thin film resonators and a reception filter including piezoelectric thin film resonators and an elastic wave resonator. The piezoelectric thin film resonators of the transmission filter and the piezoelectric thin film resonators and the elastic wave resonator of the reception filter are provided on the same substrate.

### BACKGROUND OF THE INVENTION

1. Field of the Invention

The present invention relates to a duplexer and more specifically relates to a duplexer including a piezoelectric thin film resonator and an elastic wave resonator.

2. Description of the Related Art

Heretofore, it has been proposed that a transmission filter of a duplexer is constituted by a BAW resonator (piezoelectric thin film resonator) and a reception filter is constituted by a BAW resonator and a SAW resonator (surface acoustic wave resonator), respectively and, as illustrated in the cross sectional view of FIG. 10, a SAW chip CH1 and a BAW chip CH2 are flip-chip mounted using bumps BU on a support substrate 2. See, for example, Japanese Unexamined Patent Application Publication No. 2008-504756.

However, in such a structure, since a duplexer is constituted by at least two chips of the SAW chip CH1 and the BAW chip CH2, the size of the duplexer increases. Moreover, the performance cannot be increased.

### SUMMARY OF THE INVENTION

In view of the above-described circumstances, preferred embodiments of the present invention provide a duplexer that achieves a reduction in the size and an increase in the performance.

A duplexer according to a preferred embodiment of the present invention includes a transmission filter including a piezoelectric thin film resonator, and a reception filter including a piezoelectric thin film resonator and an elastic wave resonator. The piezoelectric thin film resonator of the transmission filter and the piezoelectric thin film resonator and the elastic wave resonator of the reception filter are provided on the same substrate.

In this structure, the transmission filter or the reception filter may also preferably include elements other than the resonators, such as inductors.

According to this structure, all of the resonators constituting the transmission filter and the reception filter are provided on one substrate. Thus, compared with the case where a duplexer is constituted using two or more chips formed in different substrates as in former examples, a reduction in the size and an increase in the performance of a duplexer can be achieved.

Preferably, the piezoelectric thin film resonator of the transmission filter and the piezoelectric thin film resonator and the elastic wave resonator of the reception filter are provided on one principal surface of the substrate. A temperature-characteristics improving film arranged to improve the temperature characteristics of the reception filter is preferably provided on the other principal surface of the substrate.

In this case, the temperature characteristics of a portion constituted by the elastic wave resonators of the reception filter (e.g., vertically coupled surface acoustic wave filter) are improved and also deterioration of characteristics resulting from differences in the temperature characteristics of a portion constituted by the elastic wave resonator (e.g., vertically coupled surface acoustic wave filter) and a portion constituted by the piezoelectric thin film resonator in the reception filter do not arise. Thus, the performance of the duplexer can be further increased.

Preferably, the elastic wave resonator of the reception filter is disposed between the substrate and each of the piezoelectric thin film resonator of the transmission filter and the piezoelectric thin film resonator of the reception filter.

In this case, the substrate area can be made small by disposing the elastic wave resonator of the reception filter on the substrate, and disposing the piezoelectric thin film resonator of the transmission filter and the piezoelectric thin film resonator of the reception filter thereon, and thus a further reduction in size of the duplexer can be achieved.

Specifically, the duplexer can be constituted according to various preferred embodiments of the present invention as follows.

In one preferred embodiment, the elastic wave resonator of the reception filter is provided on a piezoelectric substrate provided on the same substrate.

In this case, the piezoelectric thin film resonator of the transmission filter and the piezoelectric thin film resonator of the reception filter can be directly provided on the same substrate and the elastic wave resonator of the reception filter can be provided on a piezoelectric substrate disposed on the same substrate.

In another preferred embodiment, the same substrate is a piezoelectric substrate.

In this case, since the piezoelectric thin film resonator of the transmission filter, the piezoelectric thin film resonator of the reception filter, and the elastic wave resonator of the reception filter can be directly provided on the same substrate, two or more kinds of substrates need not to use, and thus a reduction in the size of the duplexer can be achieved.

In another preferred embodiment, the piezoelectric thin film resonator of the transmission filter and the piezoelectric thin film resonator of the reception filter are provided on the elastic wave resonator of the reception filter.

In this case, since the substrate area can be made small by disposing the piezoelectric thin film resonator of the transmission filter and the piezoelectric thin film resonator of the reception filter on the elastic wave resonator of the reception filter, a further reduction in size of the duplexer can be achieved.

According to various preferred embodiments of the present invention, a reduction in the size and an increase in the performance of a duplexer can be achieved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an electric circuit diagram of a duplexer (Example 1).

FIG. 2 is a block diagram of a duplexer (Example 1).

FIG. 3 is a cross sectional view of a piezoelectric thin film resonator (Example 1).

FIG. 4 is a cross sectional view of a piezoelectric thin film resonator (Modification 1 of Example 1).

FIG. 5 is a block diagram of a vertically coupled filter (Example 1).

FIG. 6 is a block diagram of a vertically coupled filter (Modification 2 of Example 1).

FIG. 7 is a block diagram of a duplexer (Example 2).

FIG. 8 is a block diagram of a duplexer (Example 3).

FIG. 9 is a block diagram of a duplexer (Example 4).

FIG. 10 is a block diagram of a duplexer (Former Example).

### DETAILED DESCRIPTION OF THE PREFERRED EMBODIMENTS

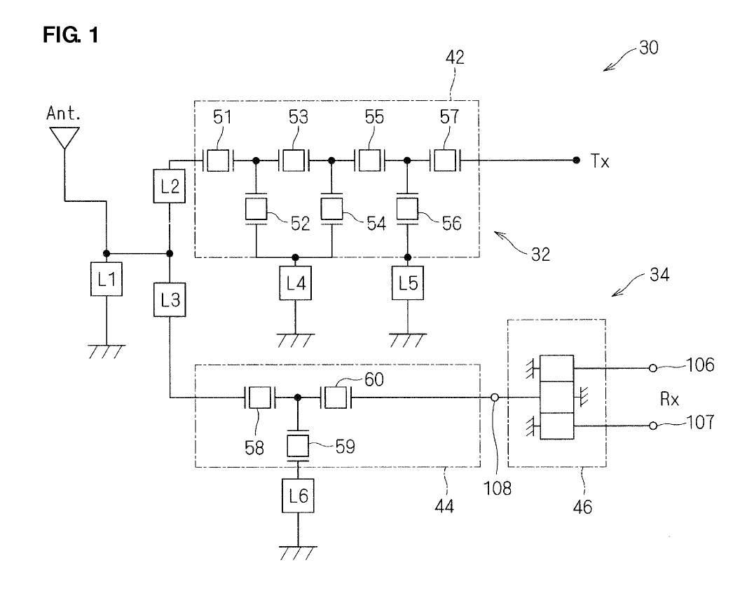

Hereinafter, preferred embodiments of the present invention will be described with reference to FIGS. 1 to 9.

### Example 1

A duplexer 30 of Example 1 will be described with reference to FIGS. 1 to 6.

As illustrated in the electric circuit diagram of FIG. 1, the duplexer 30 of Example 1 includes resonators 51 to 60 and a vertically coupled filter 46, in which a transmission filter 32 and a reception filter 34 are constituted between the antenna end and a Tx end and between the antenna end and an Rx end, respectively. Inductors L1 to L6 may be provided to the duplexer 30 itself or may be externally attached to the duplexer 30.

The transmission filter 32 provided between the antenna end and the Tx end includes four series resonators 51, 53, 55, and 57 and three parallel resonators 52, 54, and 56 that are connected in a ladder arrangement. The reception filter 34 provided between the antenna end and the Rx end includes the resonators 58, 59, and 60 and the vertically coupled filter 46.

To the Tx end, an unbalance signal can be input/output. The reception filter has a function of converting an unbalance signal to a balance signal, and thus a balance signal is output to the Rx end.

The resonators 51 to 57 of the transmission filter 32 and the resonators 58 to 60 of the reception filter 34 preferably are piezoelectric thin film (BAW) resonators, for example. The vertically coupled filter 46 of the reception filter 34 is a vertically coupled surface acoustic wave filter preferably including surface acoustic wave (SAW) resonators (not illustrated), for example.

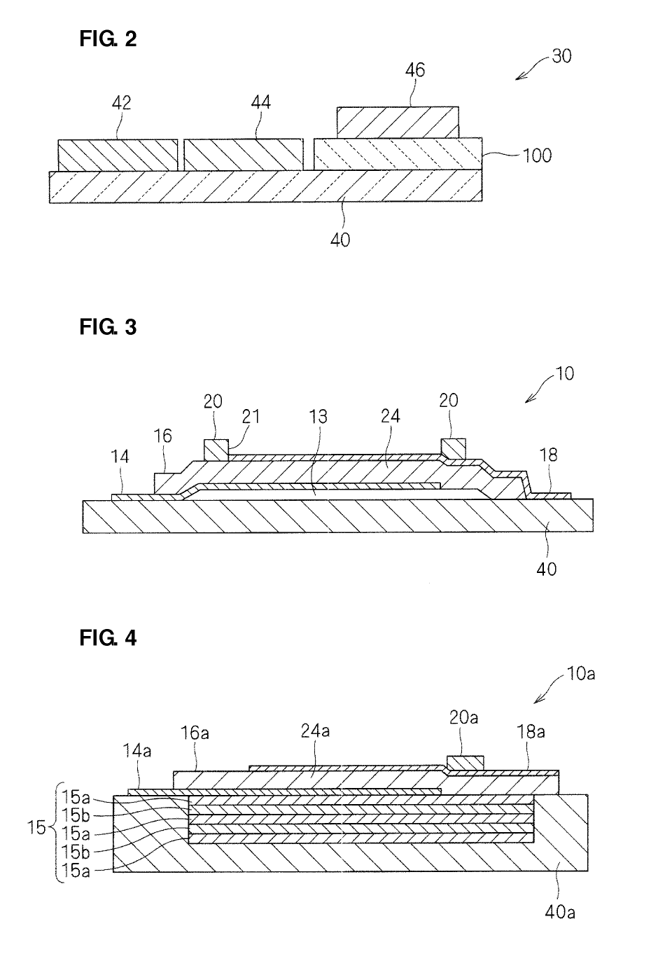

A transmission side BAW resonator group 42 including the resonators 51 to 57 of the transmission filter 32, a reception side BAW resonator group 44 including the resonators 58 to 60 of the reception filter 34, and the vertically coupled filter 46 of the reception filter 34 are provided on the same substrate 40 as schematically illustrated in the block diagram of FIG. 2.

For example, the BAW resonator group 42 of the transmission filter and the BAW resonator group 44 of the reception filter are provided on the Si board 40 and the vertically coupled filter 46 is provided on a piezoelectric substrate 100 disposed on the Si board 40.

The BAW resonators of the BAW resonator groups 42 and 44 preferably have the same construction as an air gap type BAW resonator 10 illustrated in the cross sectional view of FIG. 3.

More specifically, in the BAW resonator 10 illustrated in FIG. 3, a Ti/Al lower electrode 14, an AlN piezoelectric film 16, a Ti/Al upper electrode 18, and an AlN addition film 20 are laminated in this order on the Si board 40.

The lower electrode 14 has a portion supported by the Si board 40 and a portion spaced apart from the Si board 40 through a gap 13. On the portion spaced apart from the substrate, a vibration portion 24 is provided in which the piezoelectric film 16 is sandwiched between the lower electrode 14 and the upper electrode 18. The gap 13 is formed by disposing a sacrificial layer on the Si board 40, and then removing the sacrificial layer after laminating the lower electrode 14 on the sacrificial layer.

The BAW resonators of the BAW resonator groups 42 and may be constituted in the same manner as in an acoustic reaction type BAW resonator 10a illustrated in the cross sectional view of FIG. 4.

More specifically, as illustrated in FIG. 4, in the BAW resonator 10a, a vibration portion 24a in which a piezoelectric film 16a is sandwiched between electrodes 14a and 18a is provided on an acoustic reaction layer 15 in place of a gap. The acoustic reaction layer 15 is preferably formed by laminating at least three or more layers 15a and 15b each having a length equivalent to the ¼ wavelength of the operating frequency and having different impedances on sn Si substrate 40a.

In FIG. 4, the acoustic reaction layer 15 is provided in a concave portion of the Si substrate 40a. However, a structure may be acceptable in which the acoustic reaction layer is provided on the substrate plane, and a vibration portion is disposed thereon.

The wiring between the BAW resonators of the BAW resonator groups 42 and 44 can be simultaneously formed with upper electrodes or lower electrodes of the BAW resonators, for example.

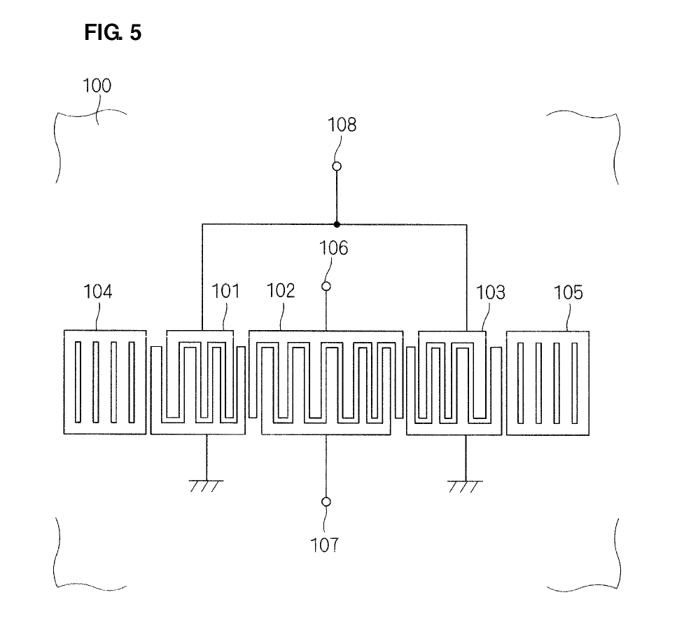

The vertically coupled filter 46 preferably is a vertically coupled surface acoustic wave (SAW) filter including a surface acoustic wave (SAW) resonator on the piezoelectric substrate 100 as illustrated in the block diagram of FIG. 5.

Specifically, on the piezoelectric substrate 100 preferably including 40±5° Y-cut X-propagation LiTaO₃, three comb-shaped or screen-shaped IDT (Inter-Digital Transducer) electrodes 101, 102, and 103 and two reflectors 104 and 105 disposed so as to sandwich the electrodes from right and left in FIG. 5 that are individually made of aluminum (Al) are disposed along the propagation direction of the surface acoustic wave. The right and left IDT electrodes 101 and 103 are connected to an unbalance signal terminal 108 and the central IDT electrode 102 is connected to balance signal terminals 106 and 107.

A temperature compensating film containing SiO₂ arranged to improve the temperature characteristics is preferably provided on the IDT electrodes 101, 102, and 103 and the reflectors 104 and 105 and the circumference thereof.

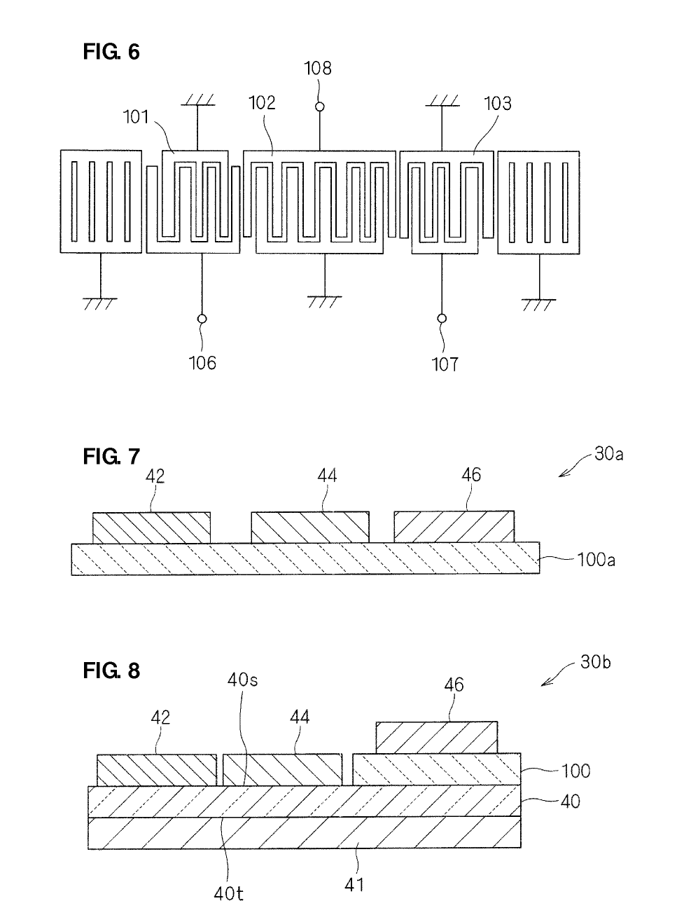

As illustrated in the block diagram of FIG. 6, a structure may be acceptable in which the central IDT electrode 102 is connected to the unbalance signal terminal 108 and the right and left IDT electrodes 101 and 103 are connected to the balance signal terminals 106 and 107, respectively.

The piezoelectric substrate 100 is stuck to the Si substrate 40 but a piezoelectric thin film in place of the piezoelectric substrate 100 may be provided on the Si substrate 40, and then the vertically coupled SAW filter 46 may be formed on the piezoelectric thin film.

As in the duplexer 30 of Example 1, when all the resonators are provided on the one substrate 40, a reduction in the size and an increase in the performance of the duplexer can be achieved.

### Example 2

A duplexer 30a of Example 2 will be described with reference to FIG. 7.

The duplexer 30a of Example 2 is preferably constituted in approximately the same manner as the duplexer 30 of Example 1 as schematically illustrated in the block diagram of FIG. 7. Hereinafter, the same components as those of Example are designated by the same reference characters and differences will be mainly described.

The duplexer 30a of Example 2 is preferably constituted in approximately the same manner as the duplexer 30 of Example 1 and the BAW resonator group 42 of the transmission filter, the BAW resonator group 44 of the reception filter, and the vertically coupled filter 46 of the reception filter are provided on the same substrate 100a.

However, unlike the duplexer 30 of Example 1, the same substrate 100a on which the BAW resonator groups 42 and 44 and the vertically coupled filter 46 are provided is a piezoelectric substrate, and the vertically coupled filter 46 of the reception filter is directly disposed on the piezoelectric substrate 100a.

The BAW resonators of the BAW resonator group 42 of the transmission filter and the BAW resonator group 44 of the reception filter provided on the piezoelectric substrate 100a preferably have an air gap type structure which is easily produced.

Since all the resonators can be provided on the piezoelectric substrate 100a, the duplexer 30a of Example 2 does not need to use or have two or more kinds of substrates and can be easily reduced in size.

### Example 3

A duplexer 30b of Example 3 will be described with reference to FIG. 8.

As schematically illustrated in the block diagram of FIG. 8, in the duplexer 30b of Example 3, a temperature-characteristics improving film 41 is preferably added to the structure of the duplexer 30 of Example 1.

More specifically, the temperature-characteristics improving film 41 is arranged on a surface 40t opposite to a surface 40s on which the resonators are provided of the substrate 40 and is preferably made of a material whose coefficient of linear expansion is different from that of the substrate 40. For example, an Al₂O₃ film 41 is provided on the undersurface 40t of the Si substrate 40. The temperature-characteristics improving film 41 may be made of materials other than Al₂O₃, e.g., materials, such as SiO₂.

By adding the temperature-characteristics improving film 41, the duplexer 30b of Example 3 can improve the temperature characteristics of the vertically coupled SAW filter and deterioration of characteristics resulting from differences in the temperature characteristics between the vertically coupled SAW filter 46 and the BAW resonators 58, 59, and 60 do not occur. Thus, a further increase in the performance of the duplexer can be achieved.

### Example 4

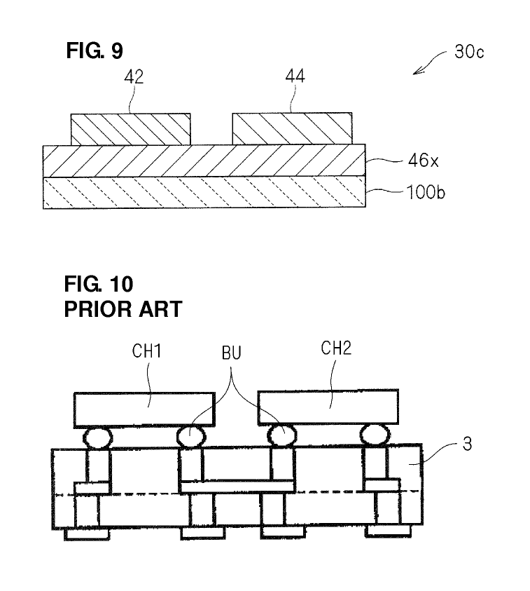

A duplexer 30c of Example 4 will be described with reference to FIG. 9.

As schematically illustrated in the block diagram of FIG. 9, in the duplexer 30c of Example 4, a vertically coupled filter 46x of the reception filter is provided on a piezoelectric substrate 100b, and then the BAW resonator group 42 of the transmission filter and the BAW resonator group 44 of the reception filter are provided on the vertically coupled filter 46x of the reception filter.

Specifically, the IDT electrodes, the reflectors, or the like of the vertically coupled filter illustrated in FIG. 5 or 6 are provided to define the vertically coupled filter 46x of the reception filter on the piezoelectric substrate 100b, and then a silicon oxide which is a temperature-characteristics compensating film is formed so as to cover the top thereof. On the silicon oxide, the BAW resonator group 42 of the transmission filter and the BAW resonator group 44 of the reception filter are provided.

The vertically coupled filter 46x may be constituted by an elastic boundary wave resonator.

Since, in the duplexer 30c of Example 4, the substrate area can be made small by disposing the BAW resonator groups 42 and 44 on the vertically coupled filter 46x, a further reduction in size of the duplexer can be achieved.

### CONCLUSION

As described above, a reduction in the size and an increase in the performance of a duplexer can be achieved by a transmission filter including a piezoelectric thin film resonator, a reception filter including a piezoelectric thin film resonator and an elastic wave resonator, and providing the piezoelectric thin film resonator of the transmission filter, the piezoelectric thin film resonator of the reception filter, and the elastic wave resonator of a reception filter on the same substrate.

The present invention is not limited to the above-described preferred embodiments and can be carried out while variously modifying the same.

For example, the vertically coupled filter may be constituted by a boundary wave resonator in place of the SAW resonator.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is the claimed is:

1. A duplexer, comprising:
a transmission filter including a piezoelectric thin film resonator and a reception filter including a piezoelectric thin film resonator and an elastic wave resonator; wherein
the piezoelectric thin film resonator of the transmission filter and the piezoelectric thin film resonator and the elastic wave resonator of the reception filter are provided on the same substrate.

2. The duplexer according to claim 1, wherein the piezoelectric thin film resonator of the transmission filter and the piezoelectric thin film resonator and the elastic wave resonator of the reception filter are provided on one principal surface of the substrate; and
a temperature-characteristics improving film arranged to improve the temperature characteristics of the reception filter is provided on another principal surface of the substrate.

3. The duplexer according to claim 1, wherein the elastic wave resonator of the reception filter is disposed between the substrate and each of the piezoelectric thin film resonator of the transmission filter and the piezoelectric thin film resonator of the reception filter.

4. The duplexer according to claim 1, wherein the elastic wave resonator of the reception filter is disposed on a piezoelectric substrate disposed on the same substrate.

5. The duplexer according to claim 1, wherein the same substrate is a piezoelectric substrate.

6. The duplexer according to claim 1, wherein the piezoelectric thin film resonator of the transmission filter and the piezoelectric thin film resonator of the reception filter are provided on the elastic wave resonator of the reception filter.
